(19) United States
(12) Patent Application Publication
(10) Pub. No.: US 2015/0144951 A1
(43) Pub. Date: May 28, 2015

(54) THIN FILM TRANSISTOR ARRAY PANEL AND MANUFACTURING METHOD THEREOF

(71) Applicant: SAMSUNG DISPLAY CO., LTD., YONGIN-CITY (KR)

(72) Inventors: Doo-Na Kim, Seongnam-si (KR); Hyeon Jun Lee, Hwaseong-si (KR); Chang Ok Kim, Yongin-si (KR); Yoon Ho Kim, Seoul (KR); Ki Seong Seo, Seoul (KR); Jung Yun Jo, Namyangju-si (KR)

(73) Assignee: SAMSUNG DISPLAY CO., LTD., YONGIN-CITY (KR)

(21) Appl. No.: 14/257,791

(22) Filed: Apr. 21, 2014

(30) Foreign Application Priority Data
Nov. 26, 2013 (KR) 10-2013-0144863

(51) Int. Cl. H01L 29/786; H01L 21/02; H01L 29/66; H01L 27/15; H01L 21/8234

(52) U.S. Cl. CPC H01L 29/78603; H01L 27/156; H01L 21/8234; H01L 29/66742; H01L 21/02164
USPC 257/72; 438/34

(57) ABSTRACT

A thin film transistor array panel including: an insulation substrate, a gate line provided on the insulation substrate and including a gate electrode, a gate insulating layer provided on the gate line, a semiconductor layer provided on the gate insulating layer, and a source electrode and a drain electrode provided on the semiconductor layer and separated from each other, and the gate insulating layer includes a fluorinated silicon oxide (SiOF) layer, and the gate electrode, the semiconductor layer, the source electrode, and the drain electrode form a thin film transistor, and a threshold voltage shift value of the thin film transistor is substantially less than 4.9 V.

### CROSS-REFERENCE TO RELATED APPLICATION

This application claims priority to and the benefit of Korean Patent Application No. 10-2013-0144863 filed in the Korean Intellectual Property Office on Nov. 26, 2013, the entire content of which is incorporated herein by reference.

### BACKGROUND

1. Field

The present invention relates to a thin film transistor array panel and a manufacturing method thereof.

2. Description of the Related Art

A flat panel display may be used as a display device, and various display devices such as a liquid crystal display, an organic light emitting diode display device, a plasma display device, an electrophoretic display device, and an electrowetting display device may be used as the flat panel display.

Among the display devices, a representative liquid crystal display is currently one of the most widely used flat panel displays, and includes two display panels on which field generating electrodes such as a pixel electrode and a common electrode are formed, a liquid crystal layer interposed therebetween, and a backlight unit providing light to the display panels and the liquid crystal layer. The liquid crystal display displays an image by applying a voltage to the field generating electrodes to generate an electric field on the liquid crystal layer, determining direction of liquid crystal molecules of the liquid crystal layer, and by controlling an emission amount of light provided by the backlight unit.

Generally, a display device including a liquid crystal display includes a thin film transistor array panel. The thin film transistor array panel is formed of a gate electrode that is a portion of a gate wire, a semiconductor layer forming a channel, and a source electrode and a drain electrode that are portions of a data wire. The thin film transistor is a switching element transferring an image signal transferred through the data wire to the pixel electrode according to a scanning signal transferred through the gate wire, or interrupting the image signal.

The above information disclosed in this Background section is only for enhancement of an understanding of the background of the invention and therefore it may contain information that does not form prior art that is already known to a person of ordinary skill in the art.

### SUMMARY

The present invention has been made in an effort to provide a thin film transistor array panel for forming a gate insulating layer including SiOF, reducing a dangling bond that may occur, and increasing a lifetime of an element.

An exemplary embodiment of the present invention provides a thin film transistor array panel including: an insulation substrate; a gate line provided on the insulation substrate and including a gate electrode; a gate insulating layer provided on the gate line; a semiconductor layer provided on the gate insulating layer; and a source electrode and a drain electrode provided on the semiconductor layer and separated from each other, wherein the gate insulating layer includes a fluorinated silicon oxide (SiOF) layer, the gate electrode, the semiconductor layer, the source electrode, and the drain electrode form a thin film transistor, and a threshold voltage shift value of the thin film transistor is substantially less than 4.9 V.

The gate insulating layer has a dual-layer structure, wherein a first gate insulating layer provided below the semiconductor layer is made of a fluorinated silicon oxide layer, and a second gate insulating layer provided below the first gate insulating layer is made of a silicon oxide (SiOx) or a silicon nitride (SiNx).

The gate insulating layer has a triple-layer structure, wherein a first gate insulating layer provided below the semiconductor layer is made of a fluorinated silicon oxide layer, and a second gate insulating layer and a third gate insulating layer provided below the first gate insulating layer are made of a silicon oxide (SiOx) or a silicon nitride (SiNx).

The gate line is made of a low-resistance metal.

The first gate insulating layer is thicker than the second gate insulating layer.

The semiconductor layer includes an oxide semiconductor.

The thin film transistor array panel further includes a passivation layer for covering the source electrode, the drain electrode, and the semiconductor layer.

Another embodiment of the present invention provides a method for manufacturing a thin film transistor array panel, including: forming a gate line on an insulation substrate; forming a gate insulating layer on the gate line by using silicon tetrafluoride (SiF₄) gas; forming a semiconductor layer on the gate insulating layer; and forming a data line including a source electrode and a drain electrode on the semiconductor layer, wherein the gate electrode, the semiconductor layer, the source electrode, and the drain electrode form a thin film transistor, and a threshold voltage shift value of the thin film transistor is substantially less than 4.9 V.

The gate insulating layer is formed by chemical vapor deposition.

The threshold voltage shift value is reduced when an amount of silicon tetrafluoride (SiF₄) gas for all gas used by the chemical vapor deposition method is increased.

The gate insulating layer is formed to have a dual-layer structure, wherein a first gate insulating layer provided below the semiconductor layer is made of a fluorinated silicon oxide (SiOF) layer, and a second gate insulating layer provided below the first gate insulating layer is made of a silicon oxide (SiOx) or a silicon nitride (SiNx).

The gate insulating layer has a triple-layer structure, wherein a first gate insulating layer provided below the semiconductor layer is made of a fluorinated silicon oxide (SiOF) layer, and a second gate insulating layer and a third gate insulating layer provided below the first gate insulating layer are made of a silicon oxide (SiOx) or a silicon nitride (SiNx).

The gate line is formed with a low-resistance metal.

The first gate insulating layer is thicker than the second gate insulating layer.

The semiconductor layer includes an oxide semiconductor.

The method may further include forming a passivation layer for covering the source electrode, the drain electrode, and the semiconductor layer.

According to the above-described thin film transistor array panel, a dangling bond between the semiconductor layer and the gate insulating layer may be reduced and reliability of the thin film transistor may be improved.

### BRIEF DESCRIPTION OF THE DRAWINGS

FIG. 1 shows a top plan view of a thin film transistor array panel according to an exemplary embodiment of the present invention.

FIG. 2 shows a cross-sectional view along lines II-II′ and II′-II″ in the thin film transistor array panel of FIG. 1.

FIG. 3A and FIG. 3B show cross-sectional views of a thin film transistor array panel according to another exemplary embodiment of the present invention.

FIG. 4 to FIG. 8 show a process for manufacturing a thin film transistor array panel according to an exemplary embodiment of the present invention.

FIG. 9A to FIG. 17 show experimental data of a thin film transistor according to an exemplary embodiment of the present invention.

### DETAILED DESCRIPTION

Hereinafter, exemplary embodiments of the present invention will be described in detail with reference to the accompanying drawings. As those skilled in the art would realize, the described embodiments may be modified in various different ways, all without departing from the spirit or scope of the present invention. On the contrary, exemplary embodiments introduced herein are provided to make the disclosed content thorough and complete, and sufficiently transfer the spirit of the present invention to those skilled in the art.

In the drawings, the thickness of layers, films, panels, regions, etc., are exaggerated for clarity. It will be understood that when a layer is referred to as being “on” another layer or substrate, it can be directly on the other layer or substrate, or intervening layers may also be present. Like reference numerals designate like elements throughout the specification.

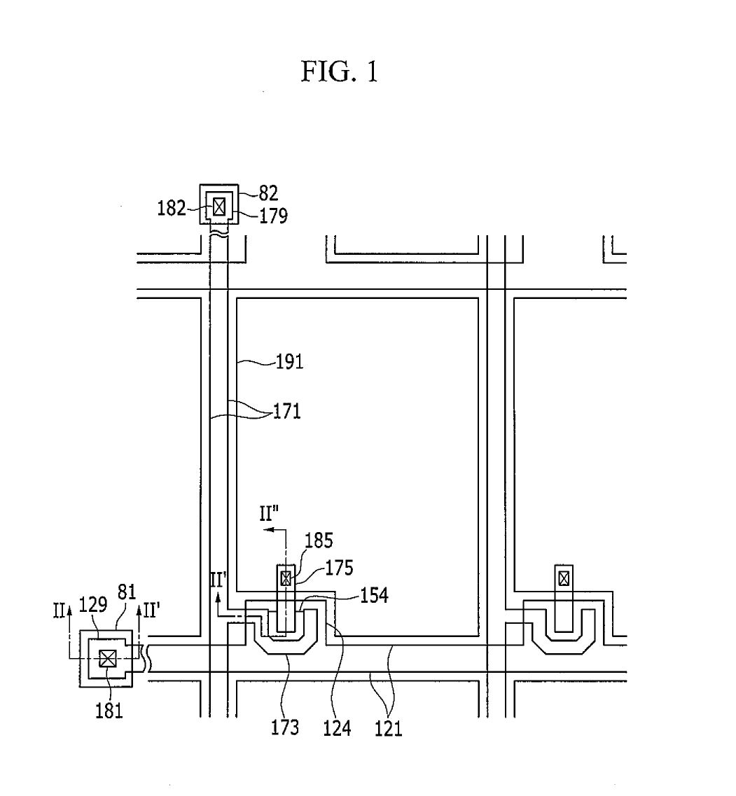

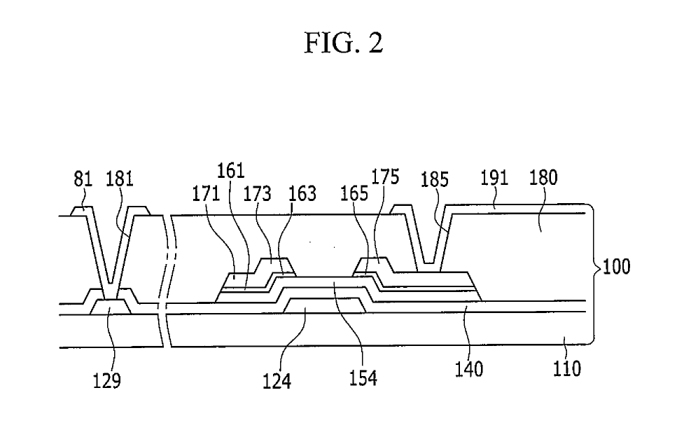

A thin film transistor array panel according to an exemplary embodiment of the present invention will now be described in detail with reference to the drawings. FIG. 1 shows a top plan view of a thin film transistor array panel according to an exemplary embodiment of the present invention and FIG. 2 shows a cross-sectional view along lines II-II′ and II-II″ of FIG. 1.

Referring to FIG. 1 and FIG. 2, a thin film transistor array panel 100 according to the present exemplary embodiment will now be described.

A plurality of gate wires extending in a first direction and a plurality of data wires extending in a second direction that cross the first direction are positioned on a first insulating substrate 110 made of transparent glass or plastic. A plurality of pixel portions are defined by the gate wires and the data wires on the first insulating substrate 110.

A gate line 121 transfers a gate signal and mainly extends in a horizontal direction. Each gate line 121 includes a plurality of gate electrodes 124 protruding from the gate line 121 and a gate pad 129 that is a wide end portion for connection with another layer or a gate driver (not illustrated).

The gate electrode 124 may have a same low-resistance metal pattern as the gate wire. In the exemplary embodiment of the present invention, the gate electrode 124 is a single layer as illustrated, however the gate electrode may be a dual layer.

For example, when the gate electrode 124 is a dual layer, the gate electrode 124 may have a structure where a lower metal layer is formed of any one selected from aluminum (Al) and aluminum neodymium (Al—Nd) and an upper metal layer is formed of molybdenum (Mo) and are sequentially laminated.

The lower metal layer is a layer acting as a passage for an electrical signal, which is an original function of the wire, and is formed of aluminum (Al) or aluminum neodymium (Al—Nd) having low resistivity.

The upper metal layer is a layer positioned to protect the lower metal layer, and serves to prevent a hillock of aluminum (Al) occurring in a subsequent process at a high temperature and reduces contact resistance between the pixel electrode and the lower metal layer.

A gate insulating layer 140 made of an insulating material such as silicon nitride is positioned on the gate line 121. FIG. 2 shows the gate insulating layer 140 with a single layer according to the exemplary embodiment of the present invention, and without being restricted to this, the gate insulating layer 140 may have a dual layer or a triple layer, which will be described later as another exemplary embodiment.

The gate insulating layer 140 includes a fluorinated silicon oxide (SiOF) layer. The fluorinated silicon oxide layer has a strong inter-molecular bonding force and reduces an influence applicable to a semiconductor layer 154 by a dangling bond included in the gate insulating layer 140.

The semiconductor layer 154 is made of amorphous silicon, polysilicon, or an oxide semiconductor and is provided on the gate insulating layer 140. The exemplary embodiment of the present invention provides the semiconductor layer 154 made of an IGZO semiconductor, and without being restricted to this, any materials having a switching characteristic are allowable.

The semiconductor layer 154 mainly extends in a vertical direction, and includes a plurality of projections extending toward the gate electrode 124.

A plurality of ohmic contact stripes 161 and ohmic contact islands 165 are positioned on the projection of the semiconductor layer 154. The ohmic contact stripe 161 has a plurality of projections 163, and a projection 163 and an ohmic contact island 165 form a pair to be positioned on the projection of the semiconductor layer 154.

A plurality of data wires 171, a plurality of source electrodes 173 connected to the plurality of data wires 171, and a plurality of drain electrodes 175 facing the source electrodes 173 are positioned on the ohmic contacts 161 and 165 and the gate insulating layer 140.

The data wire 171 transfers a data signal and mainly extends in a vertical direction to cross the gate line 121. The source electrode 173 may extend toward the gate electrode 124 to have a U shape, but this is just an example, and the source electrode 173 may have variously modified shapes.

The drain electrode 175 is separated from the data wire 171, and extends upwardly from the middle of the U-shaped source electrode 173. The data wire 171 includes a data pad 179 having an area for connection with another layer or the data driver (not illustrated).

Although not illustrated in the drawings, the data wire 171, the source electrode 173, and the drain electrode 175 may have a dual-layered structure of an upper layer and a lower layer. The upper layer may be formed of copper (Cu) or a copper alloy, and the lower layer may be formed of any one of titanium (Ti), tantalum (Ta), molybdenum (Mo), and alloys thereof.

The data wire 171, the source electrode 173, and the drain electrode 175 may have a tapered lateral surface.

The ohmic contacts 161 and 165 exist only between the semiconductor layer 154 therebeneath and the data wire 171 and the drain electrode 175 thereon, and reduce contact resistance therebetween. Further, the ohmic contacts 161, 163, and 165 may have substantially the same plane pattern as the data wire 171, the source electrode 173, and the drain electrode 175.

In the projection of the semiconductor layer 154, there is an exposed portion that is not covered by the data wire 171 and the drain electrode 175, such as a portion between the source electrode 173 and the drain electrode 175. The semiconductor layer 154 has substantially the same plane pattern as the ohmic contacts 161 and 165 except for the exposed portion of the projection.

A gate electrode 124, a source electrode 173, and a drain electrode 175 form a thin film transistor (TFT) together with the projection of the semiconductor layer 154, and the channel of the thin film transistor is formed in the projection between the source electrode 173 and the drain electrode 175.

The thin film transistor has a threshold voltage, and a voltage between a gate electrode and a source electrode of the thin film transistor must be greater than the threshold voltage so that a driving current may be generated to the thin film transistor. However, electrons generated by a negative voltage applied through the gate electrode undergo photo-assisted injection to form a trap on a semiconductor layer interface so the threshold voltage is problematically shifted.

The driving current of the thin film transistor is varied by the shifted threshold voltage, and the pixels resultantly generate luminance non-uniformity. Hence, luminance uniformity is achieved by controlling the threshold voltage shift value.

The material of the gate insulating layer includes SiOF so the thin film transistor achieves luminance uniformity. In detail, the SiOF has a strong inter-molecular bonding force, so it can reduce the dangling bond, thus it can reduce an influence of the gate insulating layer to the semiconductor layer. Accordingly, the shift value of the threshold voltage is controllable, and for example, the shift value of the threshold voltage of the thin film transistor can be substantially less than 4.9 V. As the shift value of the threshold voltage becomes less, reliability of the thin film transistor is improved.

A passivation layer 180 is positioned on the data wire 171, the drain electrode 175, and the exposed portion of the projection of the semiconductor layer 154. The passivation layer 180 is made of an inorganic insulator such as silicon nitride or silicon oxide, an organic insulator, and a low dielectric insulator.

A contact hole 181 through which the gate pad 129 is exposed is formed in the passivation layer 180 and the gate insulating layer 140. Further, a contact hole 182 through which the data pad 179 of the data wire 171 is exposed and a contact hole 185 through which an end of the drain electrode 175 is exposed are formed in the passivation layer 180.

A pixel electrode 191 and contact assistants 81 and 82 are positioned on the passivation layer 180. They may be made of a transparent conductive material such as ITO or IZO, or a reflective metal such as aluminum, silver, chromium, or an alloy thereof.

The pixel electrode 191 is physically electrically connected to the drain electrode 175 through the contact hole 185, and receives a data voltage from the drain electrode 175.

The contact assistants 81 and 82 are connected through the contact holes 181 and 182 to the gate pad 129 of the gate line 121 and the data pad 179 of the data wire 171, respectively. The contact assistants 81 and 82 complement adherence between the gate pad 129 of the gate line 121 and the data pad 179 of the data wire 171 and an external device, and protect the pads and the external device.

The gate insulating layer 140 includes SiOF having a strong hydrogen bond to reduce the dangling bond and improves reliability of the thin film transistor.

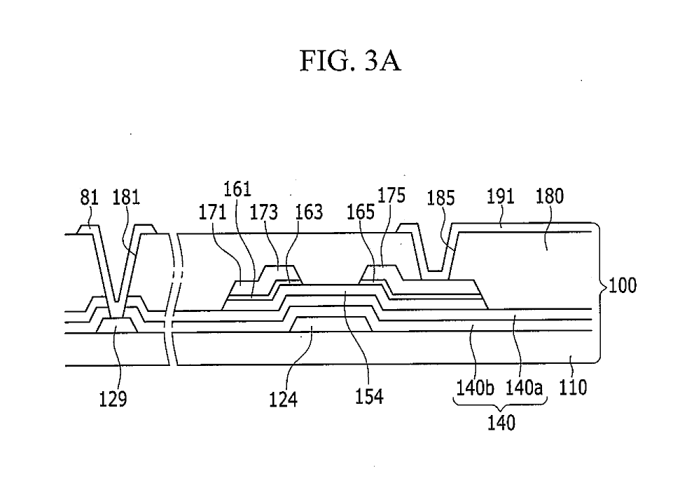

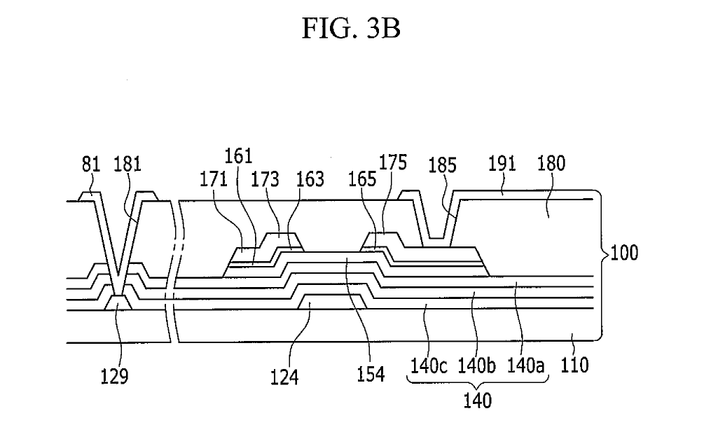

Hereinafter, referring to FIG. 3A and FIG. 3B, a thin film transistor array panel according to another exemplary embodiment of the present invention will be described. The same constituent elements as those that are described with reference to FIG. 1 and FIG. 2 will be omitted.

Referring to FIG. 3A, regarding a thin film transistor array panel 100 according to another exemplary embodiment of the present invention, a gate insulating layer 140 has a dual-layered structure.

That is, the gate insulating layer 140 having the dual-layered structure includes a first gate insulating layer 140a and a second gate insulating layer 140b. The first gate insulating layer 140a is provided below the semiconductor layer 154, and a material of the first gate insulating layer 140a is fluorinated silicon oxide (SiOF). The second gate insulating layer 140b is provided below the first gate insulating layer 140a, and a material of the second gate insulating layer 140b is a silicon oxide (SiOx) or a silicon nitride (SiNx). For example, the material of the second gate insulating layer 140b may be a silicon oxide, and gases of SiH₄ and SiF₄ may be simultaneously used so as to form a dual gate insulating layer including the silicon oxide and SiOF.

When the gate insulating layer 140 has a dual-layered structure, the first gate insulating layer 140a may be thicker than the second gate insulating layer 140b.

Referring to FIG. 3B, regarding the thin film transistor array panel according to another exemplary embodiment of the present invention, the gate insulating layer 140 has a triple-layered structure. The gate insulating layer 140 includes a first gate insulating layer 140a, a second gate insulating layer 140b, and a third gate insulating layer 140c to form the triple-layered structure. The first gate insulating layer 140a is provided below the semiconductor layer 154, and its material is fluorinated silicon oxide (SiOF). The second gate insulating layer 140b is provided below the first gate insulating layer 140a, its material may be silicon oxide (SiOx) or silicon nitride (SiNx), and it is silicon oxide in an example of the present embodiment of the invention. The third gate insulating layer 140c is provided below the second gate insulating layer 140b, its material may be silicon oxide (SiOx) or silicon nitride (SiNx), and it is silicon nitride in an example of the present embodiment of the invention.

In an embodiment where the gate insulating layer 140 includes a plurality of layers, the first gate insulating layer 140a touching the semiconductor layer 154 is a fluorinated silicon oxide layer by which the shift value of the threshold voltage is controlled.

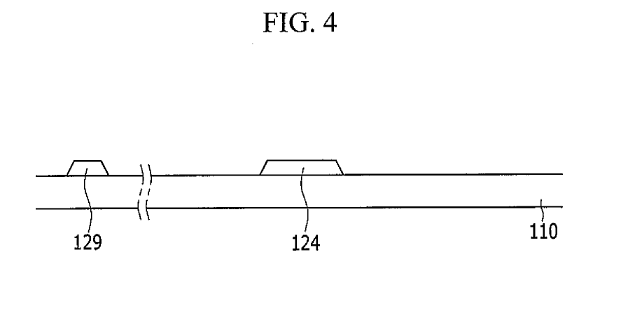

FIG. 4 to FIG. 8 show process diagrams of a method for manufacturing a thin film transistor array panel shown in FIG. 3. The same constituent elements as those that are described will be omitted. FIG. 4 to FIG. 8 illustrate the gate insulating layer 140 formed as dual layers, and without being restricted to this, it can be formed with a single layer or triple layers. To control this, a type of gas usable in a chemical deposition vaporization method can be changed.

Referring to FIG. 4, a low-resistance metal layer is stacked on the insulating substrate 110, and a photolithography process is applied thereto thereby forming a gate line 121 including a gate electrode 124 and a gate pad 129.

The gate electrode 124 can be formed with a same metal layer as the gate line. The exemplary embodiment of the present invention illustrates the gate electrode 124 as a single layer, however the gate electrode can have dual layers.

For example, when the gate electrode 124 includes dual layers, it may have a structure in which a lower metal layer made of one of aluminum (Al) and aluminum neodymium (Al—Nd) and an upper metal layer made of molybdenum (Mo) are sequentially stacked.

The lower metal layer functions as a route for electrical signals, which is a main function of the wiring, and it can be formed with copper (Cu), aluminum (Al), or aluminum neodymium (Al—Nd) with low resistivity.

The upper metal layer is provided to protect the lower metal layer, and in detail, it prevents a hillock of aluminum (Al) generated in a high-temperature subsequent process and reduces contact resistance between the pixel electrode and the lower metal layer.

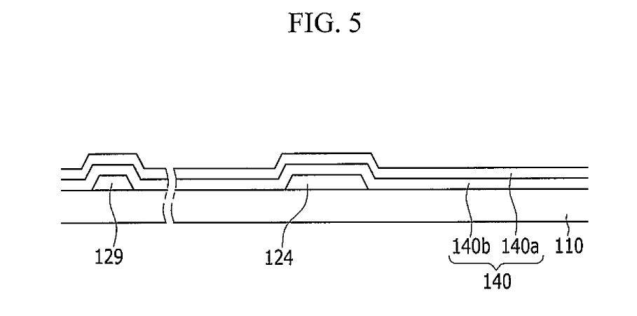

Referring to FIG. 5, a gate insulating layer 140 is formed on the gate line 121 by using a chemical vapor deposition (CVD) method. In this instance, silicon tetrafluoride (SiF₄) gas is supplied to a CVD chamber for forming the gate insulating layer 140, and in other cases, silane gas (SiH₄), hydrogen gas (H₂), and nitrogen gas (NH₃) are supplied for instance.

According to the exemplary embodiment of the present invention, the silicon tetrafluoride (SiF₄) gas must be supplied to form the gate insulating layer 140 made of the material of SiOF, and the gate insulating layer 140 with a dual-layered structure can be formed by controlling a ratio of silane gas (SiH₄) and silicon tetrafluoride (SiF₄) gas.

As the amount of the silicon tetrafluoride (SiF₄) gas in all gas used in the chemical vapor deposition method is increased, the shift value of the threshold voltage may be reduced.

Further, the exemplary embodiment of the present invention has described the gate insulating layer having dual layers, and without being restricted to this, a gate insulating layer having a single layer or a gate insulating layer having triple layers can be formed.

For example of the present invention, the gate insulating layer 140 is formed to have a dual-layer structure, the first gate insulating layer 140a provided below the semiconductor layer 154 is made of fluorinated silicon oxide, and the second gate insulating layer 140b provided below the first gate insulating layer 140a is made of a silicon oxide (SiOx) or a silicon nitride (SINx). Further, the first gate insulating layer 140a can be formed to be thicker than the second gate insulating layer 140b.

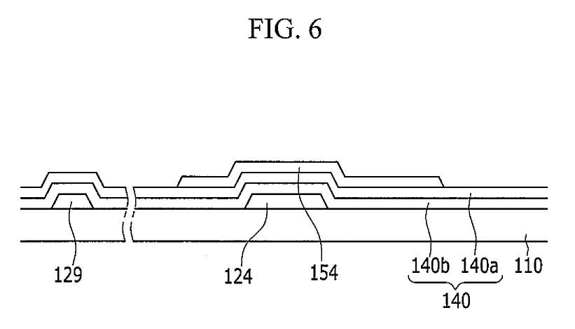

Referring to FIG. 6, a gate insulating layer 140 is formed and a semiconductor layer 154 is then formed in the CVD chamber. The semiconductor layer 154 made of amorphous silicon, polysilicon, or an oxide semiconductor can be provided, and in the exemplary embodiment of the present invention, the semiconductor layer 154 made of an IGZO semiconductor or other materials that show a switching characteristic are allowable.

The semiconductor layer 154 generally extends in a vertical direction, and it includes a plurality of projections protruded toward the gate electrode 124.

A plurality of ohmic contact stripes 161 and ohmic contact islands 165 are provided on the projections of the semiconductor layer 154. The ohmic contact stripes 161 have a plurality of projections 163, and the projections 163 and the ohmic contact islands 165 form pairs and are provided on the projections of the semiconductor layer 154.

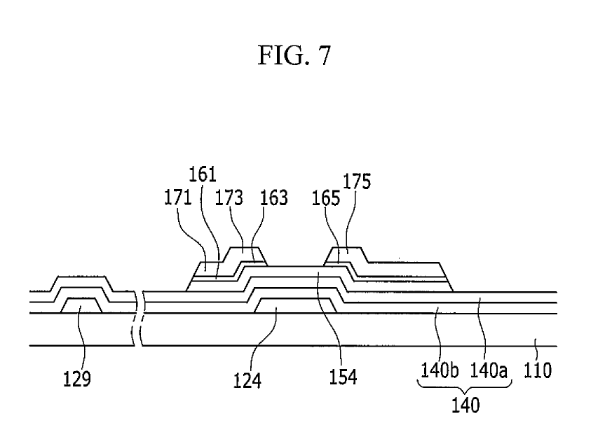

Referring to FIG. 7, when the semiconductor layer is formed, a gas such as slime gas (SiH₄), hydrogen gas (H₂), nitrogen gas (NH₃), and hydrogen phosphide gas (PH3) is supplied into the CVD chamber to form an ohmic contact 165.

A plurality of ohmic contact stripes 161 and ohmic contact islands 165 are provided on the projections of the semiconductor layer 154. The ohmic contact stripes 161 have a plurality of projections 163, and the projections 163 and the ohmic contact islands 165 form pairs and are provided on the projections of the semiconductor layer 154.

The ohmic contacts 161 and 165 are provided between the semiconductor layer 154 and the data wire 171 and drain electrode 175, and reduce contact resistance between them. Also, the ohmic contacts 161, 163, and 165 can substantially have the same flat pattern as the data wire 171, the source electrode 173, and the drain electrode 175.

A data wire 171 including a data line, a source electrode 173, and a drain electrode 175 are formed through a photolithography process. The drain electrode 175 is separated from the source electrode 173 and is provided at a top that is opposite the source electrode 173 with respect to the gate electrode 124.

The data wire 171 transmits a data signal and extends in a vertical direction to cross the gate line 121. The source electrode 173 may extend toward the gate electrode 124 to have a U shape, but this is just an example, and the source electrode 173 may have variously modified shapes.

The drain electrode 175 is separated from the data wire 171, and extends upwardly from the middle of the U-shaped source electrode 173. The data wire 171 includes a data pad 179 having an area for connection with another layer or a data driver (not illustrated).

Although not illustrated in the drawings, the data wire 171, the source electrode 173, and the drain electrode 175 may have a dual-layered structure of an upper layer and a lower layer. The upper layer may be formed of copper (Cu) or a copper alloy, and the lower layer may be formed of any one of titanium (Ti), tantalum (Ta), molybdenum (Mo), and alloys thereof.

The data wire 171, the source electrode 173, and the drain electrode 175 may have a tapered lateral surface.

One gate electrode 124, one source electrode 173, and one drain electrode 175 form one thin film transistor TFT together with the projection of the semiconductor layer 154, and the channel of the thin film transistor is formed in the projection between the source electrode 173 and the drain electrode 175.

The thin film transistor has a threshold voltage, and a voltage between a gate electrode and a source electrode of the thin film transistor must be greater than the threshold voltage so that a driving current may be generated to the thin film transistor. However, electrons generated by a negative voltage applied through the gate electrode undergo photo-assisted injection to form a trap on a semiconductor layer interface so the threshold voltage is problematically shifted.

The driving current of the thin film transistor is varied by the shifted threshold voltage, and the pixels resultantly generate luminance non-uniformity. Hence, luminance uniformity is achieved by controlling a shift value of the threshold voltage.

The material of the gate insulating layer includes SiOF so the thin film transistor achieves luminance uniformity. In detail, the SiOF has a strong inter-molecule bonding force, so it can reduce the dangling bond, thus it can reduce an influence of the gate insulating layer to the semiconductor layer. Accordingly, the shift value of the threshold voltage is controllable, and for example, the shift value of the threshold voltage of the thin film transistor can be substantially less than 4.9 V. As the shift value of the threshold voltage becomes less, reliability of the thin film transistor is improved.

The semiconductor layer 154 and the gate insulating layer 140 are exposed by etching the ohmic contact 165 positioned between the source electrode 173 and the drain electrode 175.

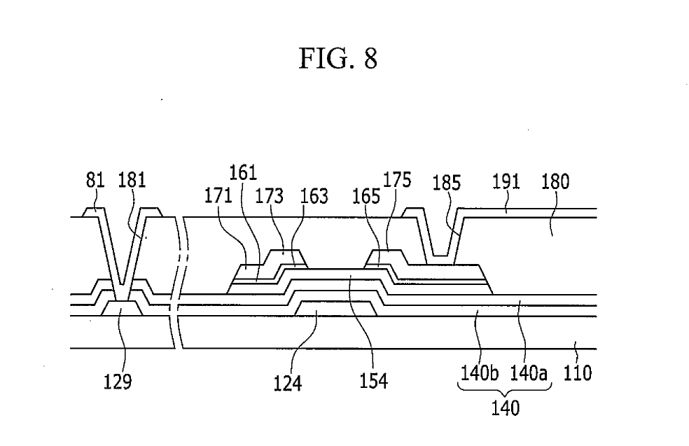

Referring to FIG. 8, when the passivation layer 180 is formed to cover the semiconductor layer 154, the contact hole 185 where a portion of the drain electrode 175 is exposed is formed through the photolithography process. A transparent conductive layer (not illustrated) is deposited on the passivation layer 180, and the pixel electrode 191 electrically connected to the drain electrode through the photolithography process is formed.

The passivation layer 180 is made of an inorganic insulator such as silicon nitride or silicon oxide, an organic insulator, and a low dielectric insulator.

A contact hole 181 through which the gate pad 129 is exposed is provided in the passivation layer 180 and the gate insulating layer 140. Further, a contact hole 182 through which the data pad 179 of the data wire 171 is exposed and a contact hole 185 through which an end of the drain electrode 175 is exposed are formed in the passivation layer 180.

A pixel electrode 191 and contact assistants 81 and 82 are positioned on the passivation layer 180. They may be made of a transparent conductive material such as ITO or IZO, or a reflective metal such as aluminum, silver, chromium, or an alloy thereof.

The pixel electrode 191 is physically and electrically connected to the drain electrode 175 through the contact hole 185, and receives a data voltage from the drain electrode 175.

The contact assistants 81 and 82 are connected through the contact holes 181 and 182 to the gate pad (end portion) 129 of the gate line 121 and the data pad (end portion) 179 of the data wire 171, respectively. The contact assistants 81 and 82 complement adherence between the gate pad 129 of the gate line 121 and the data pad 179 of the data wire 171 and an external device, and protect the pads and the external device.

A four-mask process has been described, and without being restricted to this, a five-mask process is also allowable.

The gate insulating layer 140 includes SiOF having a strong hydrogen bond to reduce the dangling bond and improve reliability of the thin film transistor.

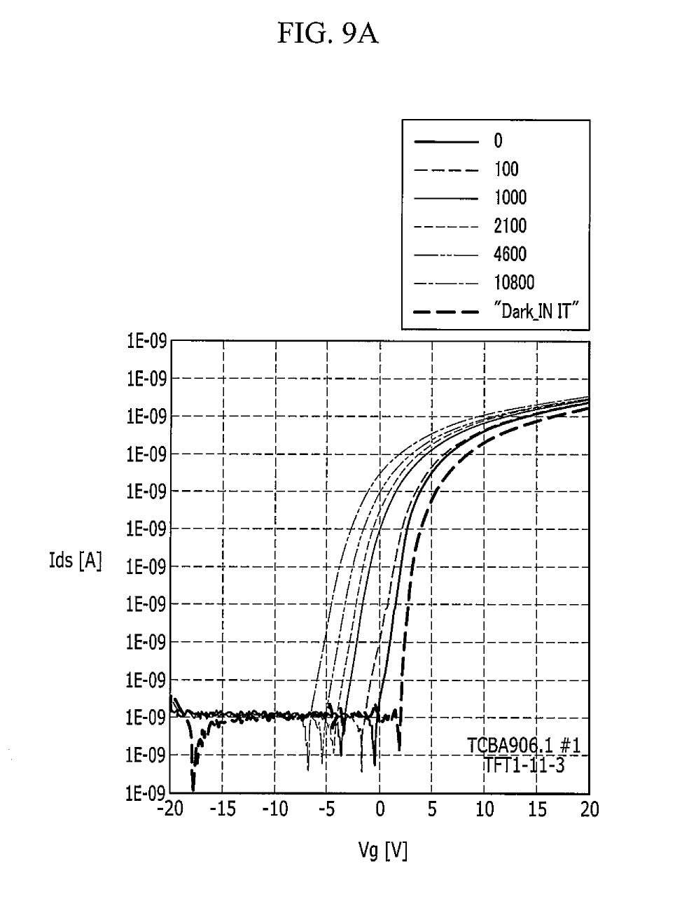

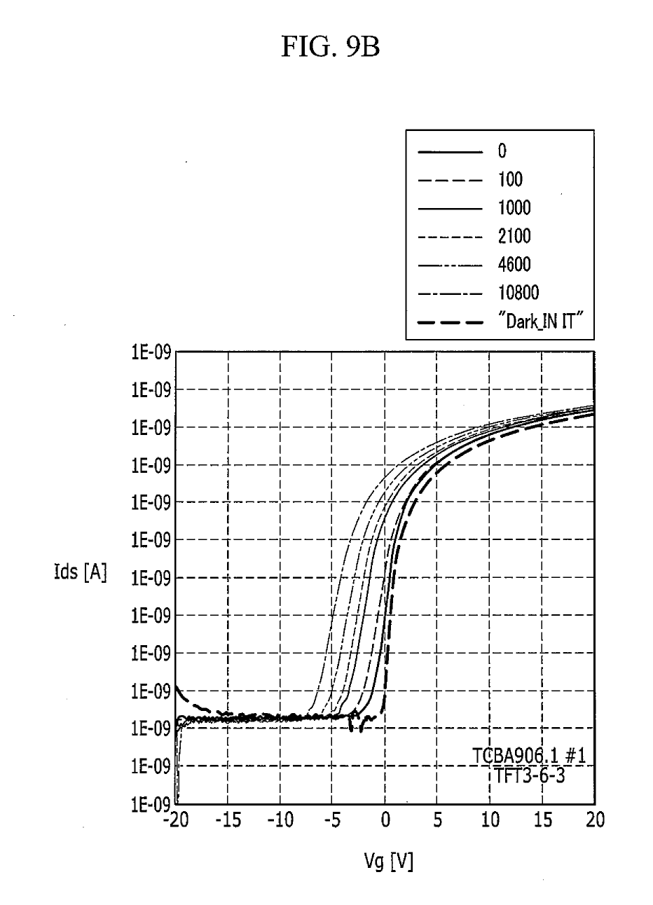

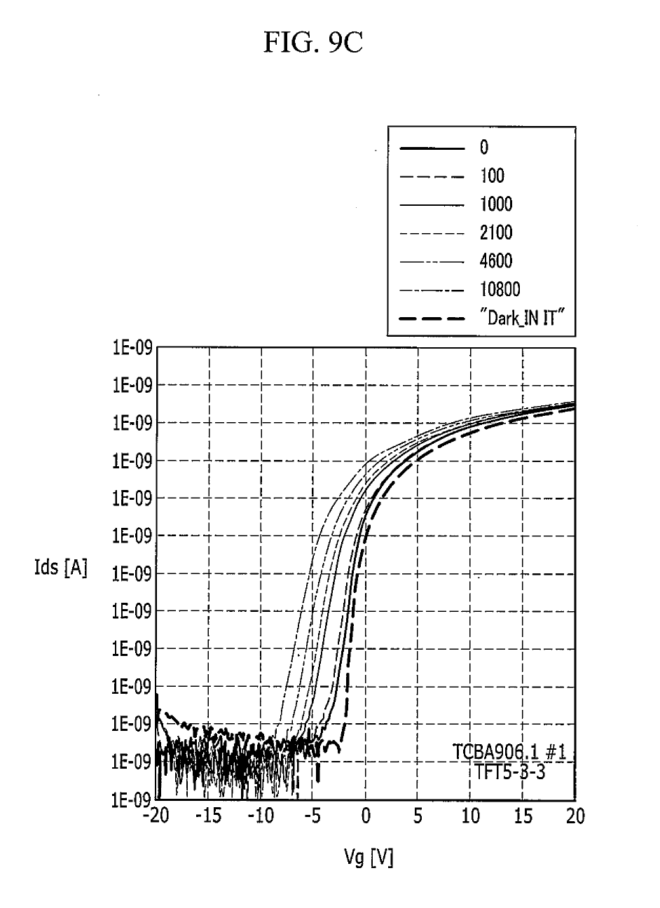

Referring to FIG. 9A to FIG. 17, a threshold voltage shift value of a thin film transistor array panel according to an exemplary embodiment of the present invention will now be described.

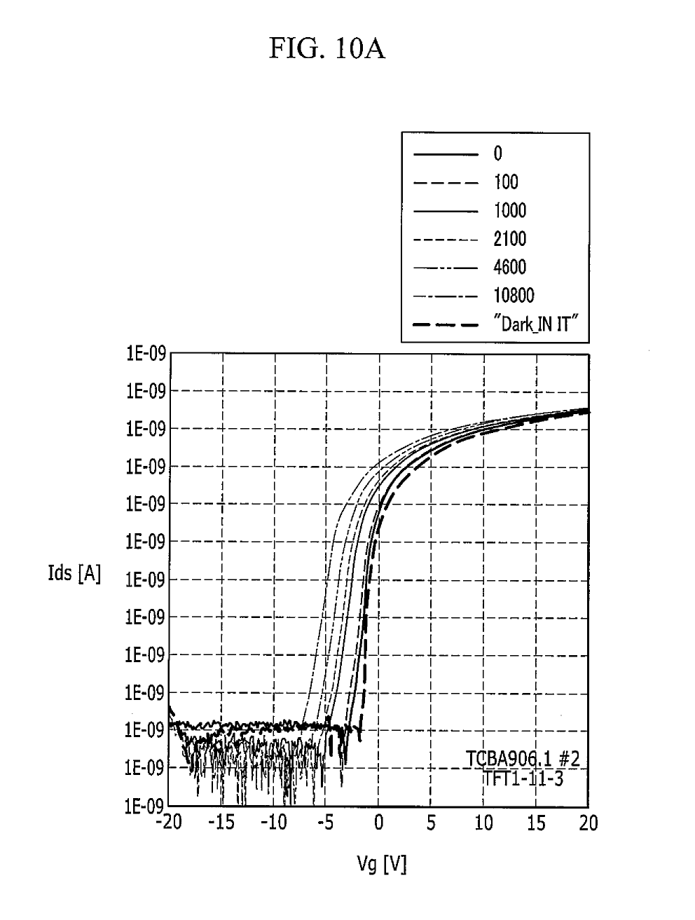

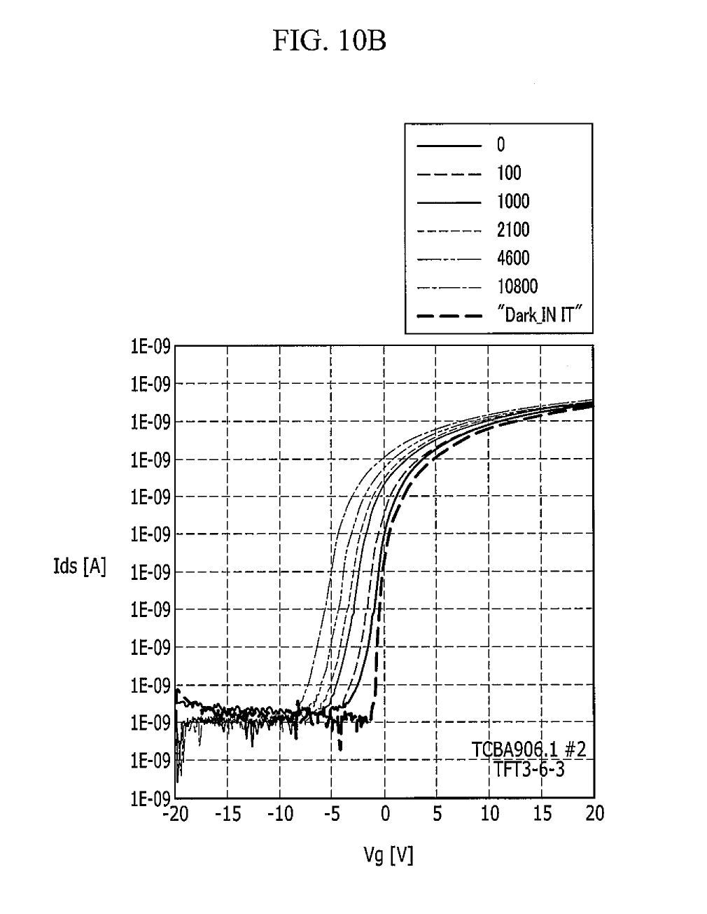

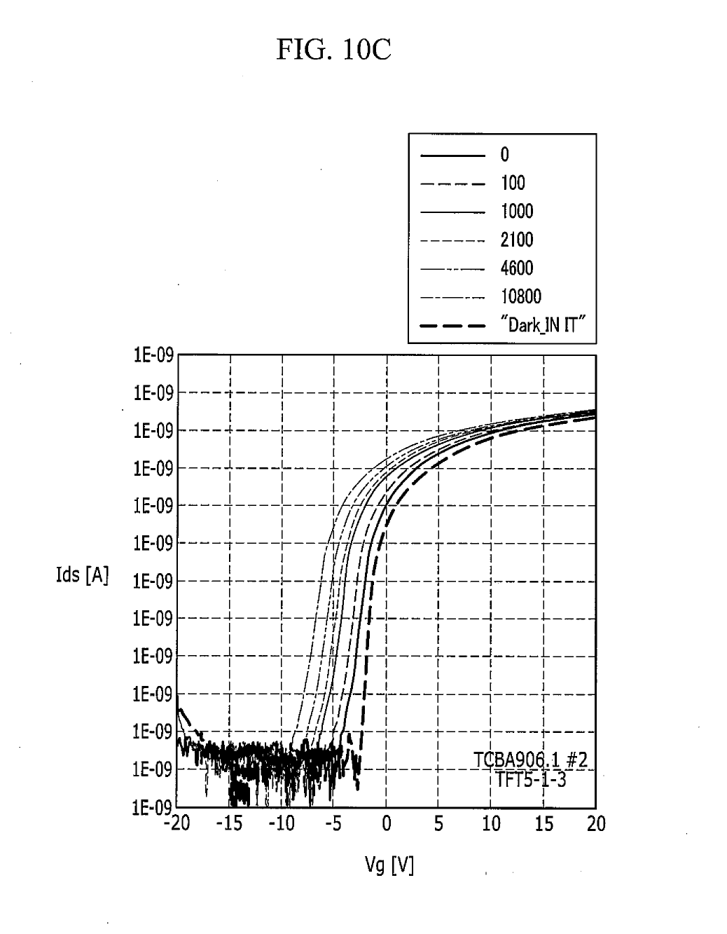

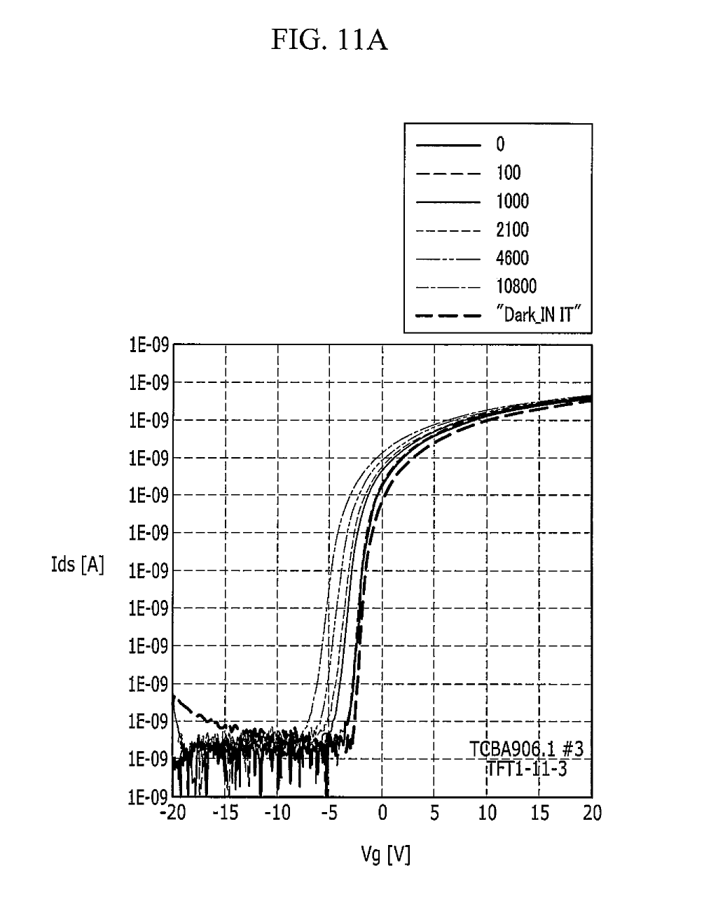

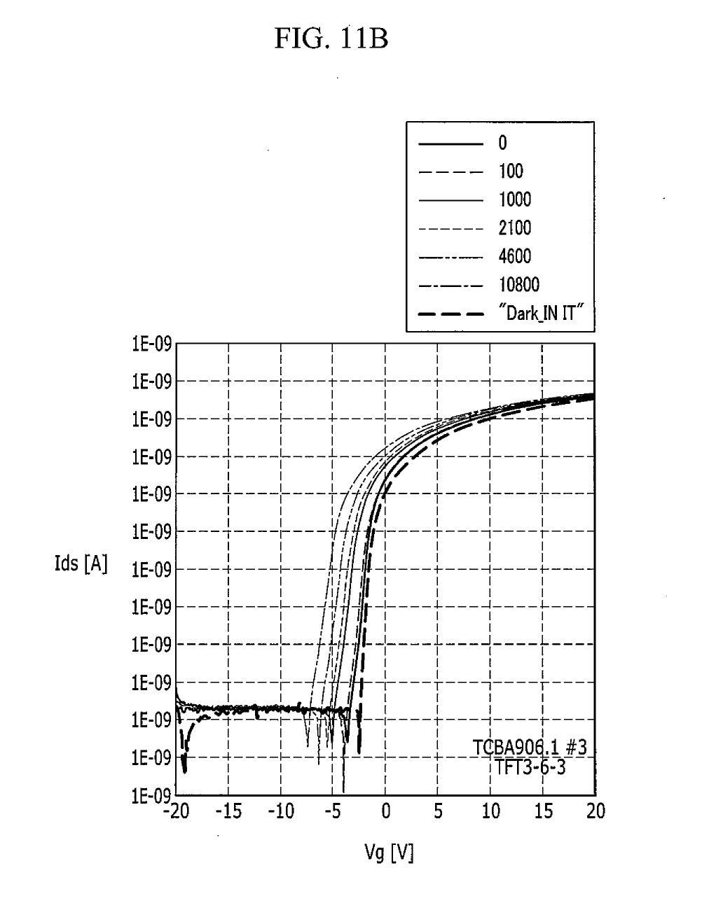

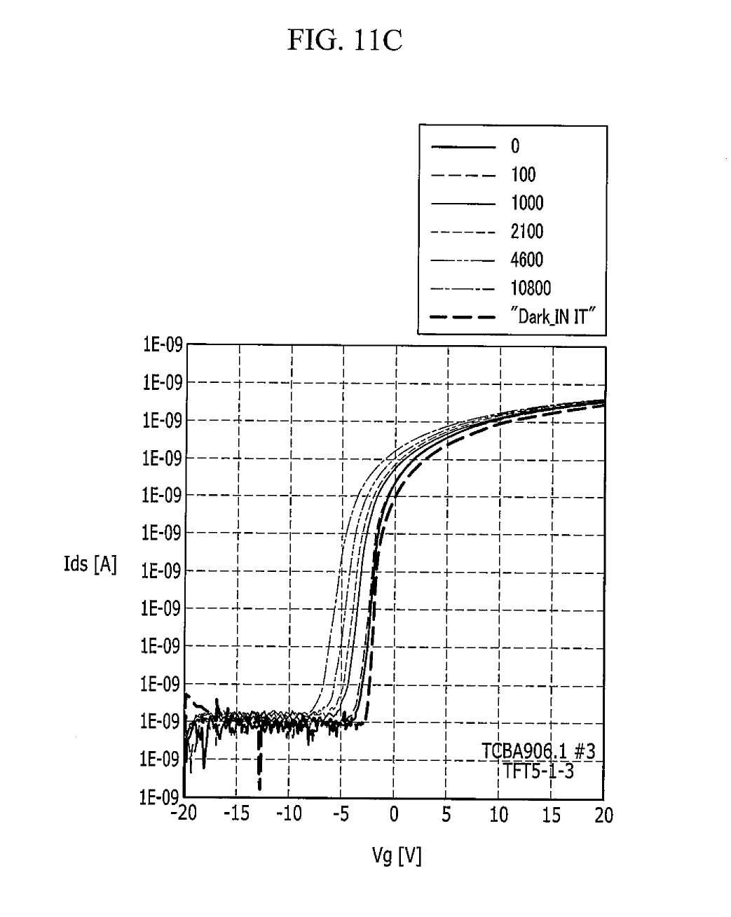

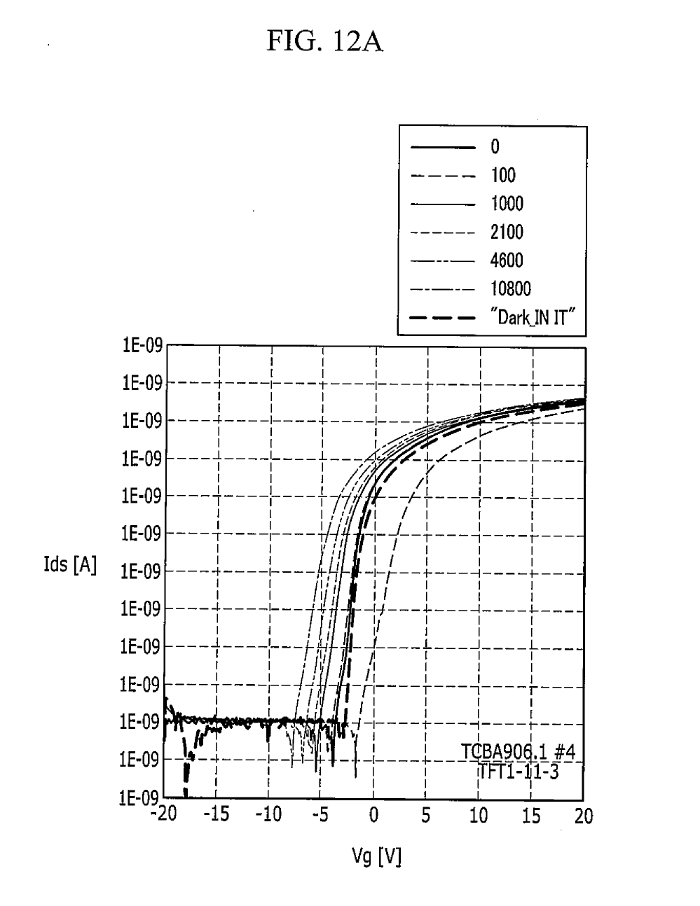

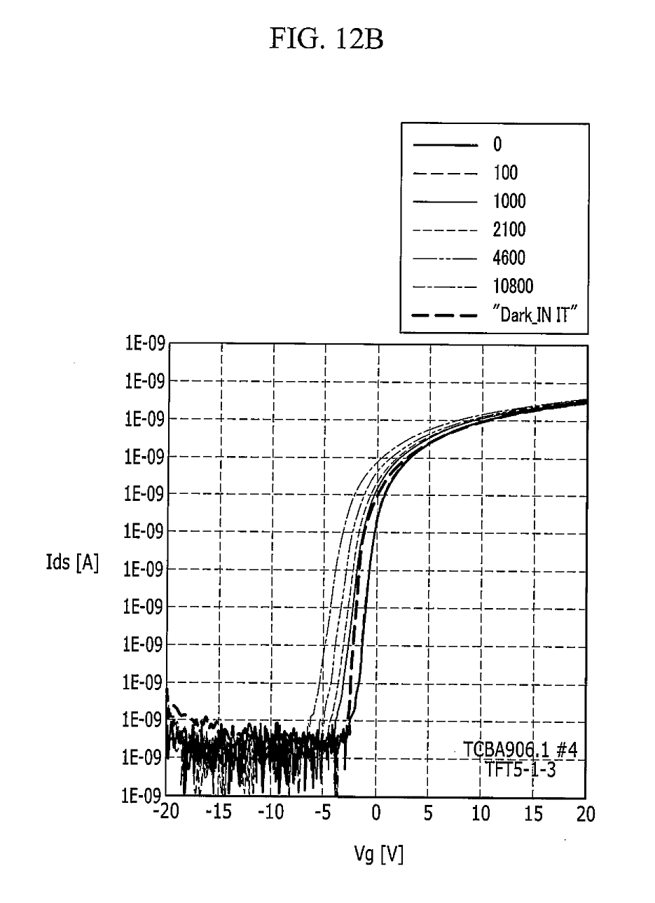

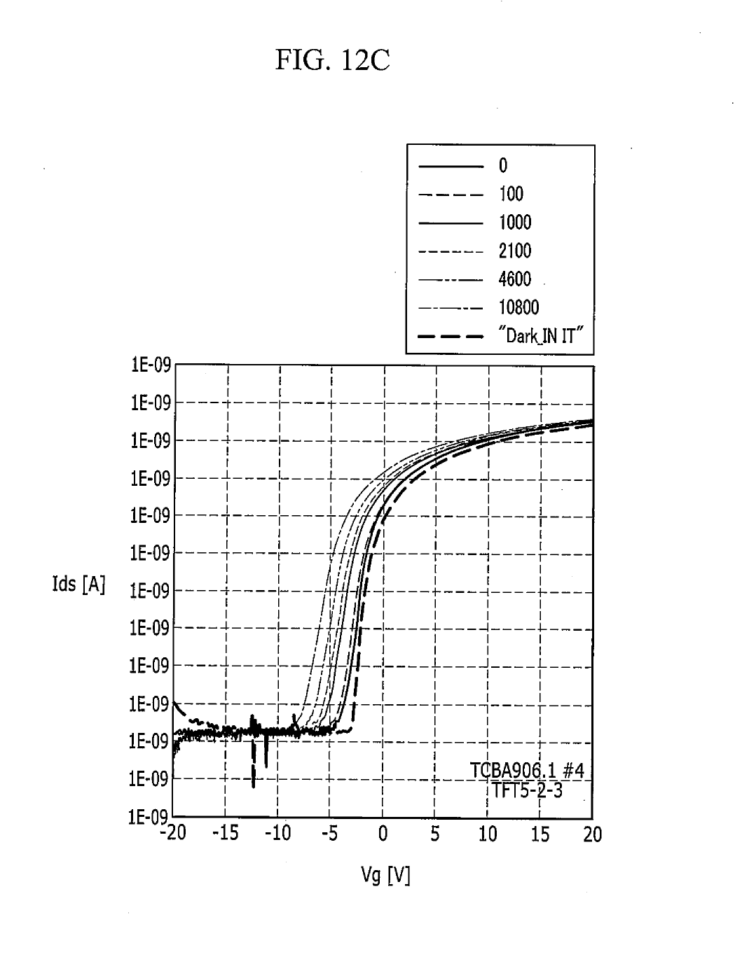

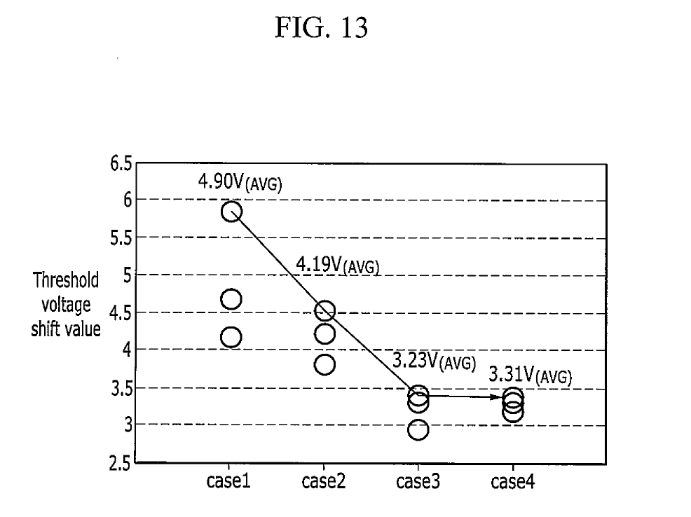

FIG. 9A to FIG. 13 show graphs on threshold voltage values for a thin film transistor array panel according to an exemplary embodiment of the present invention, showing a change of an amount of silicon tetrafluoride (SiF₄) gas when using a chemical vapor deposition method. FIGS. 9A to 9C illustrate using SiH₄ gas without using silicon tetrafluoride (SiF₄), FIG. 10A to 10C illustrate forming a gate insulating layer by injecting SiF₄:SiH₄ gas at a ratio of 1:3 for all gas used in the chemical deposition vaporization method, FIGS. 11 to 11C illustrate forming a gate insulating layer by injecting SiF₄:SiH₄ gas at a ratio of 1:2, FIG. 12A to 12C illustrate forming a gate insulating layer by injecting SiF₄:SiH₄ gas at a ratio of 1:1, and FIG. 13 illustrates a graph of threshold voltage shift values of FIG. 9A to FIG. 12C. Further, referring to FIG. 9A to FIG. 12C, each A shows a result measured at a right upper part of the thin film transistor array panel, each B shows a result measured at a center of the thin film transistor array panel, and C shows a result measured at a left lower part of the thin film transistor array panel, for a flow of current with respect to time of applying a voltage under a predetermined condition.

Referring to FIG. 9A, a current flowing to a drain electrode at a right upper part of the thin film transistor array panel when a gate voltage is applied is shown. In this instance, the graph moves to the left as time passes, and a final threshold voltage value is substantially −5.85 V.

Referring to FIG. 9B, a current flowing to the drain electrode in the center of the thin film transistor array panel by applying a gate voltage is measured. In a like manner of FIG. 9A, the graph tends to move to the left as time passes, and the final threshold voltage value is substantially −4.68 V.

Referring to FIG. 9C, a current flowing to the drain electrode by applying a gate voltage at a left Lower part of the thin film transistor array panel is shown, and in a like manner, the graph moves to the left as time passes, and the final threshold voltage value is substantially −4.17 V.

In this instance, referring to FIGS. 9A to 9C, it is found that the graph moves to the left as it goes to C from A, and as a whole, an average of the threshold voltage shift value is substantially 4.9 V.

FIGS. 10A to 10C illustrate a case of forming a gate insulating layer by injecting SiF₄:SiH₄ gas at a ratio of 1:3 for all gas used in the chemical deposition vaporization method, and a process condition is like that of FIGS. 9A-C.

Referring to FIG. 10A, a current flowing to the drain electrode when a gate voltage is applied at a right upper part of the thin film transistor array panel is shown. In this instance, the graph moves to the left as time passes, and the final threshold voltage value is substantially −3.81 V.

Referring to FIG. 10B, a current flowing to the drain electrode when a gate voltage is applied in the center of the thin film transistor array panel is measured. In a like manner of FIG. 1 OA, the graph has a tendency of moving to the left as time passes, and the final threshold voltage value is substantially −4.53 V.

Referring to FIG. 10C, a current flowing to the drain electrode by applying a gate voltage at a left lower part of the thin film transistor array panel is shown, and in a like manner, the graph moves to the left as time passes, and the final threshold voltage value is substantially −4.22 V.

In this instance, comparing FIGS. 10A to 10C, the greatest threshold voltage shift is generated in the case of B indicating positioning in the center of the thin film transistor array panel, and as a whole, the average of the threshold voltage shift value is substantially 4.19 V. That is, the SiF₄ gas is included when the gate insulating layer is formed, so when compared to FIGS. 9A-C, it is found that the shift degree of the threshold voltage is substantially reduced.

FIGS. 11A to 11C illustrate forming a gate insulating layer by injecting SiF₄:SiH₄ gas at a ratio of 1:2 for all gas used in the chemical deposition vaporization method, and a process condition is like that of FIGS. 9A-C.

Referring to FIG. 11A, a current flowing to the drain electrode when a gate voltage is applied at a right upper part of the thin film transistor array panel is shown. In this instance, the graph moves to the left as time passes, and the final threshold voltage value is substantially −2.95 V.

Referring to FIG. 11B, a current flowing to the drain electrode when a gate voltage is applied in the center of the thin film transistor array panel is measured. In a like manner of FIG. 11A, the graph has a tendency of moving to the left as time passes, and the final threshold voltage value is substantially −3.40 V.

Referring to FIG. 11C, a current flowing to the drain electrode by applying a gate voltage at a left lower part of the thin film transistor array panel is shown, and in a like manner, the graph moves to the left as time passes, and the final threshold voltage value is substantially −3.33 V.

In this instance, when comparing FIGS. 11A to 11C, in a like manner of FIGS. 10A-C, the greatest threshold voltage shift is generated in the case of B indicating positioning in the center of the thin film transistor array panel, and as a whole, the average of the threshold voltage shift value is substantially 3.23 V. That is, the SiF₄ gas is included, so when compared to FIGS. 9A-C, it is found that the shift degree of the threshold voltage is substantially reduced. Further, when compared to FIGS. 10A-C, it is found that the shift degree of the threshold voltage is reduced as the gas amount of SiF₄ is increased.

FIGS. 12A to 12C illustrates forming a gate insulating layer by injecting SiF₄:SiH₄ gas at a ratio of 1:1 for all gas used in the chemical deposition vaporization method, and a process condition is like that of FIG. 9A to 9C.

Referring to FIG. 12A, a current flowing to the drain electrode when a gate voltage is applied at a right upper part of the thin film transistor array panel is shown. In this instance, the graph moves to the left as time passes, and the final threshold voltage value is substantially −3.33 V.

Referring to FIG. 12B, a current flowing to the drain electrode when a gate voltage is applied in the center of the thin film transistor array panel is measured. In a like manner of FIG. 12A, the graph has a tendency of moving to the left as time passes, and the final threshold voltage value is substantially −3.21 V.

Referring to FIG. 12C, a current flowing to the drain electrode by applying a gate voltage at a left lower part of the thin film transistor array panel is shown, and in a like manner, the graph moves to the left as time passes, and the final threshold voltage value is substantially −3.39 V.

In this instance, when comparing FIGS. 12A to 12C, the greatest threshold voltage shift is generated in the case of B indicating positioning in the center of the thin film transistor array panel, and as a whole, the average of the threshold voltage shift value is substantially 3.31 V. The SiF₄ gas is included, so when compared to FIGS. 9A-C, it is found that the shift degree of the threshold voltage is substantially reduced, and when compared to FIGS. 11A-C, it is found that the threshold voltage shift value is increased to some degree. However, the increased amount is less, which may follow a processing error.

FIG. 13 shows average threshold voltage shift values of FIGS. 9 A to 9C to FIGS. 12A to 12C. FIG. 9A to 9C show Case 1, FIG. 10A to 10C show Case 2, FIG. 11A to 11C show Case 3, and FIG. 12A to 12C show Case 4. In detail, when the SiF₄ gas is not used for a comparative example, the threshold voltage shift degree of substantially 4.9 V is expressed, and when the SiF₄ gas is included, it is found that the threshold voltage shift value is reduced. That is, it is found that reliability of the thin film transistor is improved when the SiF₄ gas is included.

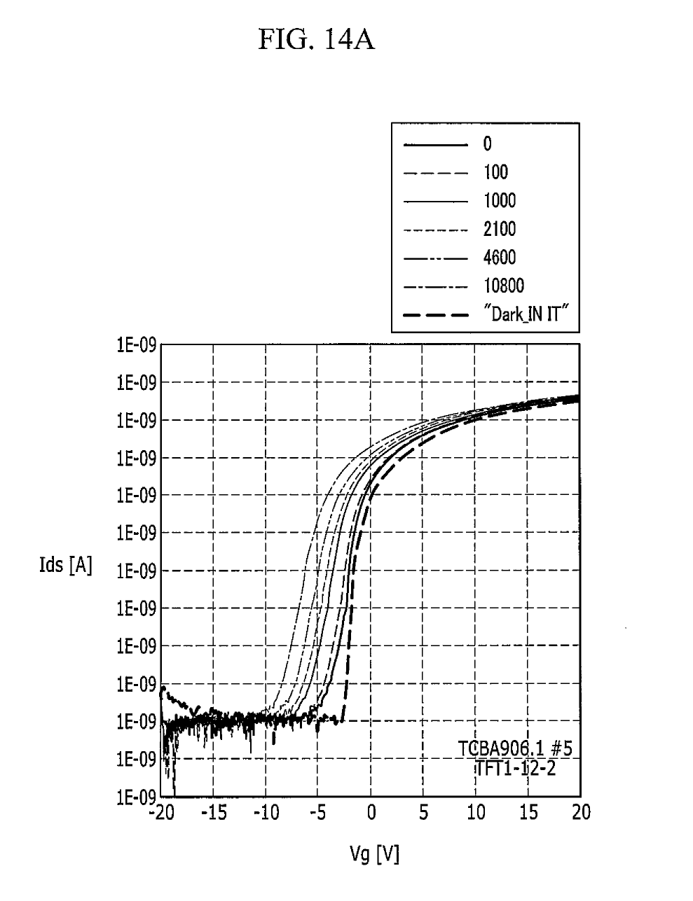

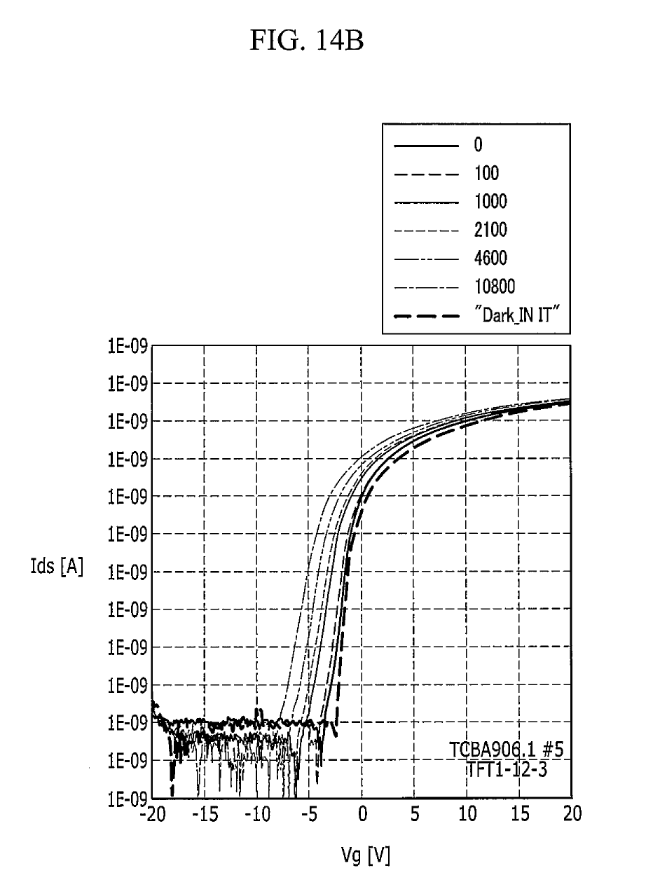

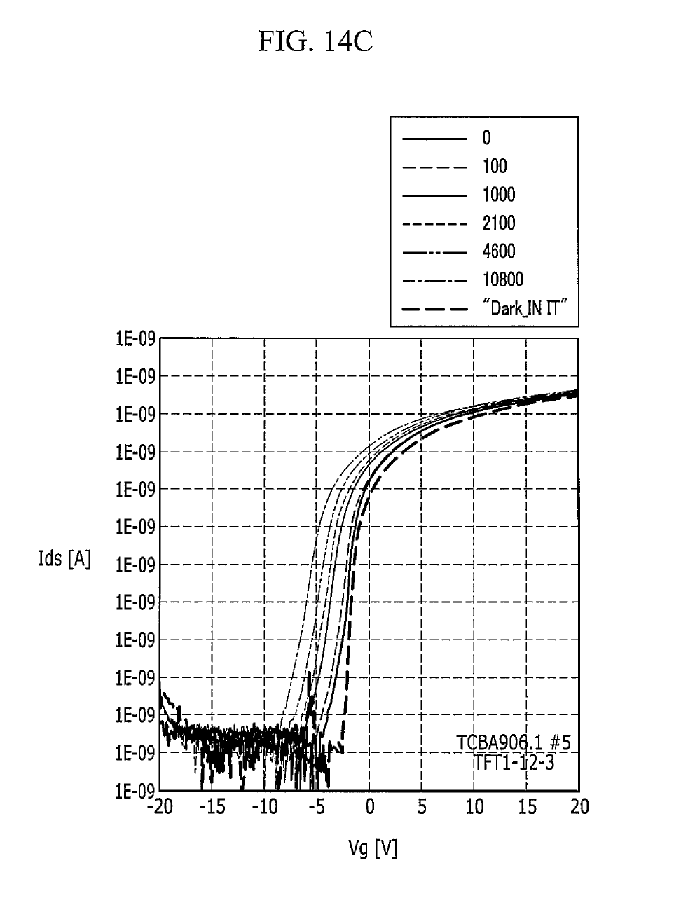

Referring to FIG. 14A to FIG. 17, performance of the thin film transistor array panel according to another exemplary embodiment of the present invention will now be described.

FIG. 14A to FIG. 14C illustrate forming a gate insulating layer with dual layers through a chemical deposition vaporization method, indicating test graphs for a case in which a first gate insulating layer provided below a semiconductor layer is made of a SiOF material, a second gate insulating layer is made of a SiOx material, and the first gate insulating layer is thicker than the second gate insulating layer.

Referring to FIG. 14A, a current flowing to a drain electrode at a right upper part of the thin film transistor array panel when a gate voltage is applied is shown. In this instance, the graph moves to the left as time passes, and the final threshold voltage value is substantially −4.26 V.

Referring to FIG. 14B, a current flowing to the drain electrode in the center of the thin film transistor array panel by applying a gate voltage is measured. In a like manner of FIG. 14A, the graph tends to move to the left as time passes, and the final threshold voltage value is substantially −3.58 V.

Referring to FIG. 14C, a current flowing to the drain electrode by applying a gate voltage at a left lower part of the thin film transistor array panel is shown, and in a like manner, the graph moves to the left as time passes, and the final threshold voltage value is substantially −3.64 V.

In this instance, referring to FIGS. 14A to 14C, the least threshold voltage shift is generated in the case of B indicating positioning in the center of the thin film transistor array panel, and as a whole, the average of the threshold voltage shift value is substantially 3.83 V. That is, since the gate insulating layer that has a dual layered structure and contacts the semiconductor layer is formed through the SiF₄ gas, it is found that the shift degree of the threshold voltage is substantially reduced compared to FIGS. 9A-C.

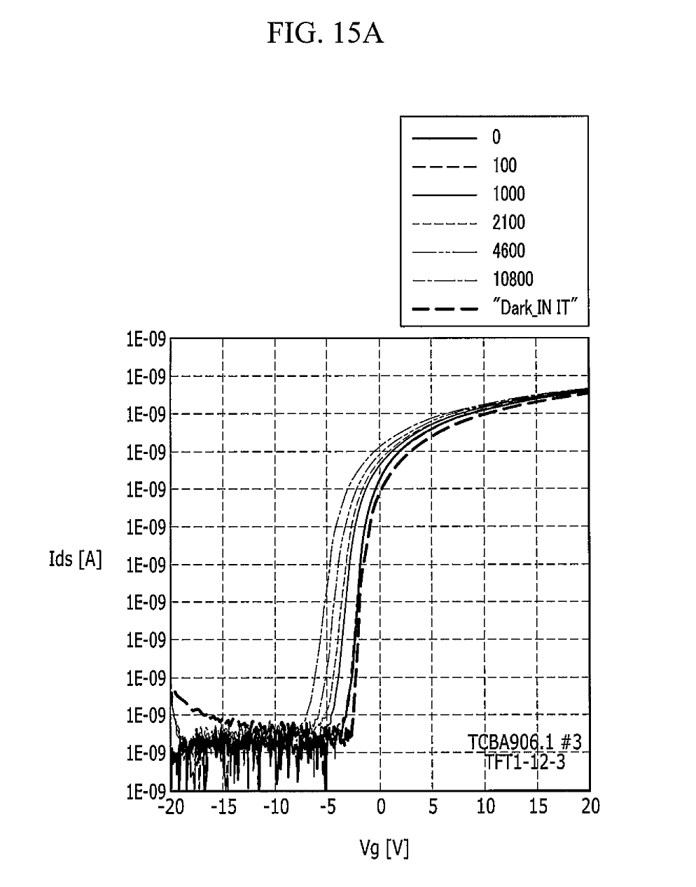

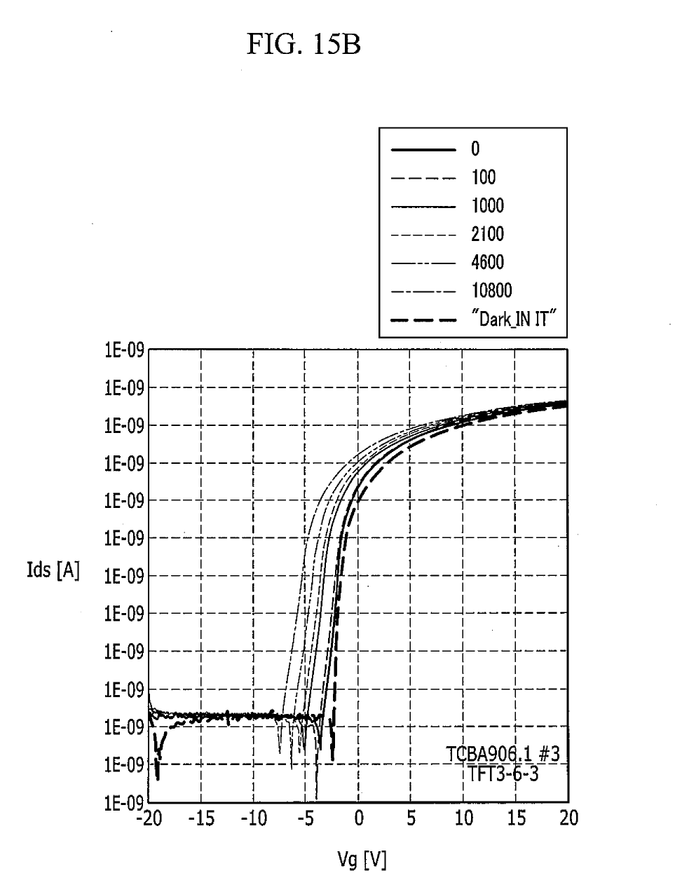

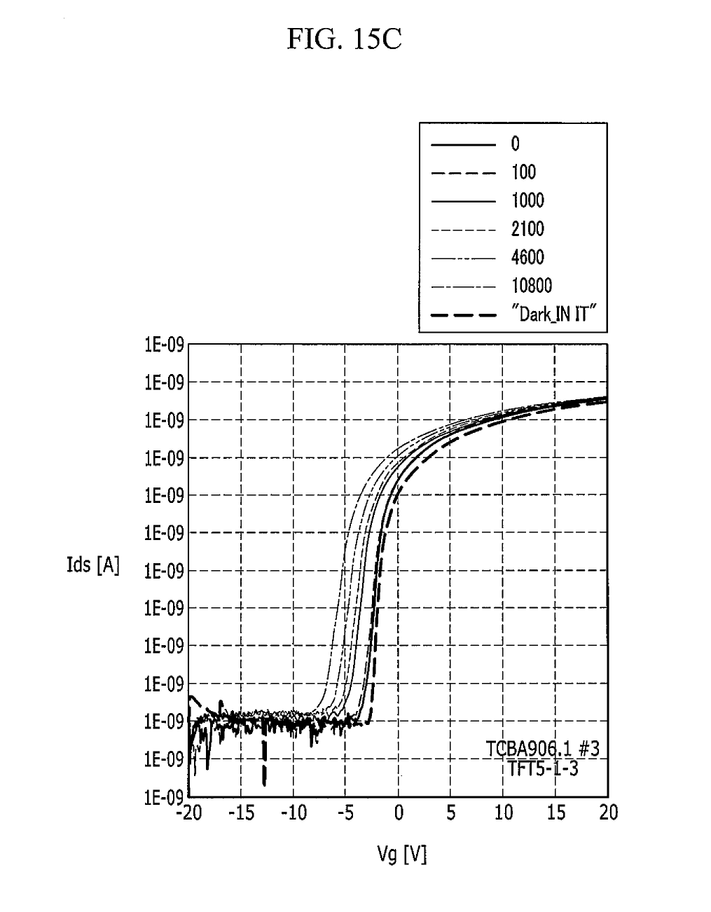

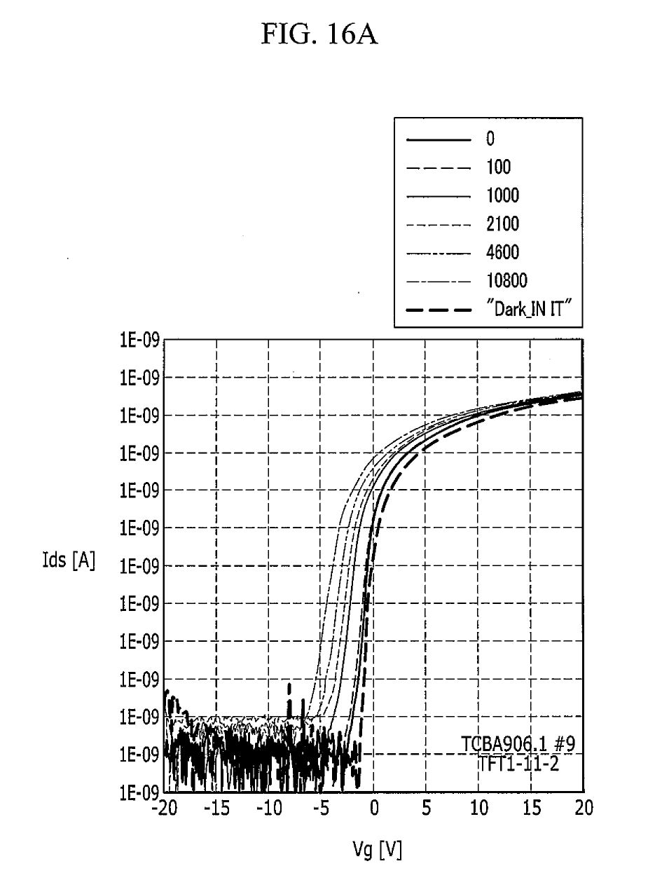

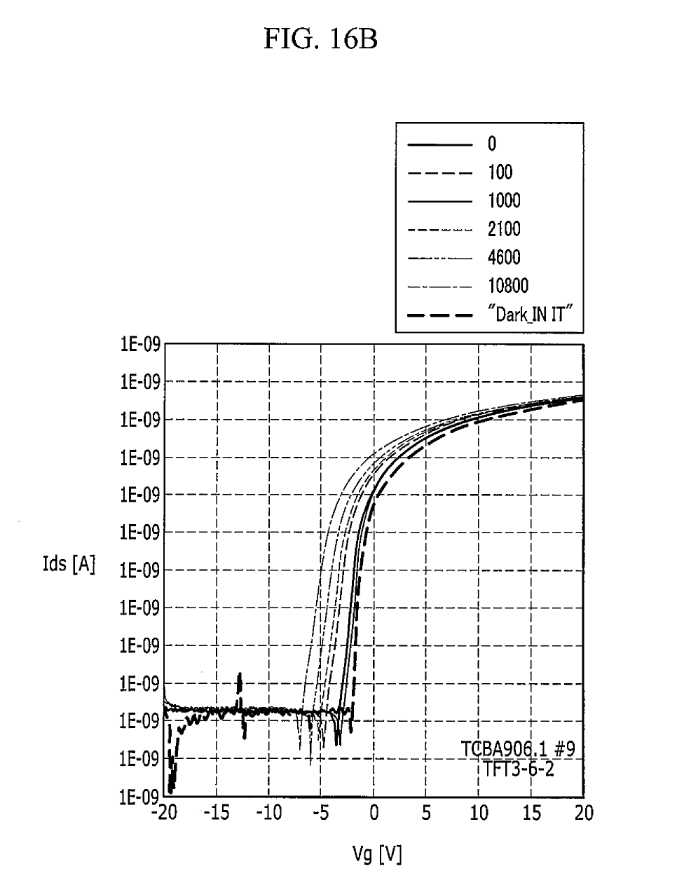

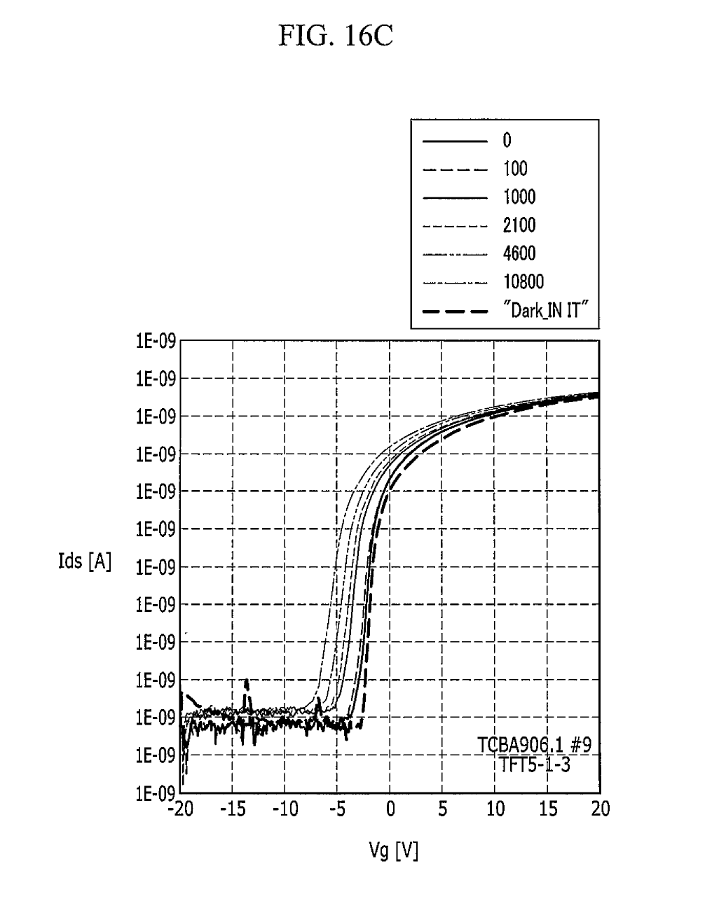

FIGS. 15A to 15C and FIGS. 16A to 16C illustrates forming a gate insulating layer by injecting SiF₄:SiH₄ gas at a ratio of 1:2 for all gas used in the chemical deposition vaporization method, wherein FIGS. 15 A to 15C show a case in which a cleansing process is performed after a gate insulating layer is formed, and FIGS. 16 A to 16C show a case in which the cleansing process is not performed after the gate insulating layer is formed.

Referring to FIG. 15A and FIG. 16A, a current flowing to the drain electrode when a gate voltage is applied at a right upper part of the thin film transistor array panel is shown. In this instance, the graph moves to the left as time passes, and the final threshold voltage values are substantially −2.95 V and −3.42 V.

Referring to FIG. 15B and FIG. 16B, a current flowing to the drain electrode when a gate voltage is applied in the center of the thin film transistor array panel is measured. In a like manner of FIG. 15A and FIG. 16A, the graph has a tendency of moving to the left as time passes, and the final threshold voltage values are substantially −3.40 V and −3.45 V.

Referring to FIG. 15C and FIG. 16C, a current flowing to the drain electrode by applying a gate voltage at a left lower part of the thin film transistor array panel is shown, and in a like manner, the graph moves to the left as time passes, and the final threshold voltage values are substantially −3.33 V and −3.30 V.

In this instance, when comparing FIGS. 11A to 11C, as a whole, averages of the threshold voltage shift values are substantially 3.23 V and 3.39 V, respectively. When the gate insulating layer is formed, the case of performing a cleansing process shows a lesser threshold voltage shift value, and such a difference is very much less and imparts no great influence to the threshold voltage shift value regarding whether to perform the cleansing process.

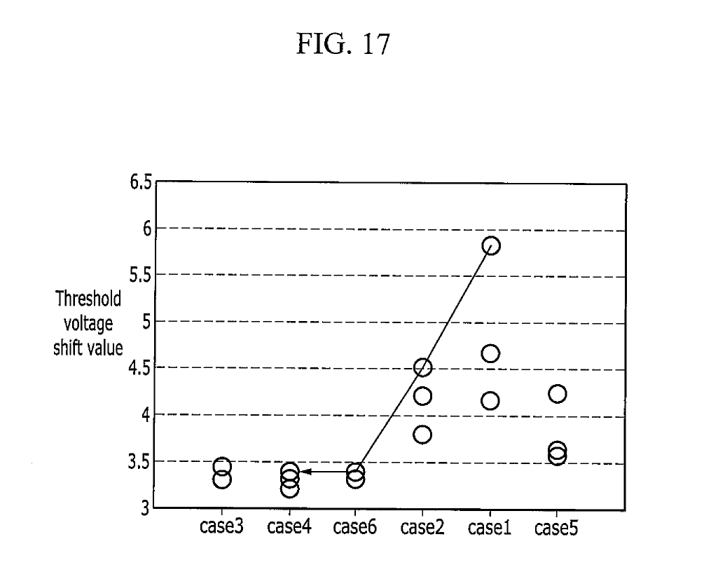

The above-described exemplary embodiment and the comparative example are shown in FIG. 17. FIG. 9A to 9C show Case 1, FIG. 10A to 10C show Case 2, FIG. 11A to 11C show Case 3, FIG. 12A to 12C show Case 4, FIG. 13 shows Case 5, and FIG. 15A to 15C show Case 6. According to the drawings, when the amount of the SiF₄ gas is increased, the threshold voltage shift value is reduced, which however does not make a big difference irrespective of cleansing.

The present exemplary embodiment has described with respect to the thin film transistor array panel applied to the liquid crystal display, and the description on the thin film transistor array panel 100 is applicable to any other types of display devices.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A thin film transistor array panel comprising:
an insulation substrate;
a gate line on the insulation substrate and including a gate electrode;
a gate insulating layer on the gate line;
a semiconductor layer on the gate insulating layer; and
a source electrode and a drain electrode on the semiconductor layer and separated from each other, wherein
the gate insulating layer includes a fluorinated silicon oxide (SiOF) layer,
the gate electrode, the semiconductor layer, the source electrode, and the drain electrode form a thin film transistor, and
a threshold voltage shift value of the thin film transistor is substantially less than 4.9 V.

2. The thin film transistor array panel of claim 1, wherein
the gate insulating layer has a dual-layer structure comprising,
a first gate insulating layer which is provided below the semiconductor layer and is made of a fluorinated silicon oxide layer, and
a second gate insulating layer which is provided below the first gate insulating layer and is made of a silicon oxide (SiOx) or a silicon nitride (SiNx).

3. The thin film transistor array panel of claim 1, wherein
the gate insulating layer has a triple-layer structure comprising,
a first gate insulating layer which is provided below the semiconductor layer and is made of a fluorinated silicon oxide layer, and
a second gate insulating layer and a third gate insulating layer which are provided below the first gate insulating layer and are made of a silicon oxide (SiOx) or a silicon nitride (SiNx).

4. The thin film transistor array panel of claim 1, wherein
the gate line is made of a low-resistance metal.

5. The thin film transistor array panel of claim 2, wherein
the first gate insulating layer is thicker than the second gate insulating layer.

6. The thin film transistor array panel of claim 1, wherein
the semiconductor layer includes an oxide semiconductor.

7. The thin film transistor array panel of claim 1, further including
a passivation layer for covering the source electrode, the drain electrode, and the semiconductor layer.

8. A method for manufacturing a thin film transistor array panel, the method comprising:
forming a gate line on an insulation substrate;
forming a gate insulating layer on the gate line by silicon tetrafluoride (SiF₄) gas;
forming a semiconductor layer on the gate insulating layer; and
forming a data line including a source electrode and a drain electrode on the semiconductor layer, wherein
the gate line, the semiconductor layer, the source electrode, and the drain electrode form a thin film transistor, and
a threshold voltage shift value of the thin film transistor is substantially less than 4.9 V.

9. The method of claim 8, wherein
the gate insulating layer is formed by chemical vapor deposition.

10. The method of claim 9, wherein
the threshold voltage shift value is reduced when an amount of the silicon tetrafluoride (SiF₄) gas used during the chemical vapor deposition is increased.

11. The method of claim 8, wherein
the gate insulating layer is formed to have a dual-layer structure comprising,
a first gate insulating layer which is provided below the semiconductor layer and is made of a fluorinated silicon oxide (SiOF) layer, and
a second gate insulating layer which is provided below the first gate insulating layer and is made of a silicon oxide (SiOx) or a silicon nitride (SiNx).

12. The method of claim 8, wherein
the gate insulating layer has a triple-layer structure comprising,
a first gate insulating layer which is provided below the semiconductor layer and is made of a fluorinated silicon oxide (SiOF) layer, and
a second gate insulating layer and a third gate insulating layer which are provided below the first gate insulating layer and are made of a silicon oxide (SiOx) or a silicon nitride (SiNx).

13. The method of claim 8, wherein
the gate line is formed with a low-resistance metal.

14. The method of claim 11, wherein
the first gate insulating layer is thicker than the second gate insulating layer.

15. The method of claim 8, wherein
the semiconductor layer includes an oxide semiconductor.

16. The method of claim 8, further including
forming a passivation layer for covering the source electrode, the drain electrode, and the semiconductor layer.
